(19) United States
(12) Patent Application Publication
(10) Pub. No.: US 2025/0010366 A1
(43) Pub. Date: Jan. 9, 2025

(54) SYSTEM AND METHOD FOR SUBZERO MOLDING, IMPRINTING, AND CASTING

(71) Applicant: Daniel S. Clark, Carmichael, CA (US)

(72) Inventor: Daniel S. Clark, Carmichael, CA (US)

(21) Appl. No.: 18/709,803

(22) PCT Filed: Nov. 14, 2022
(86) PCT No.: PCT/US2022/049752

§ 371 Date: May 13, 2024

Related U.S. Application Data
(60) Provisional application No. 63/279,160, filed on Nov. 14, 2021.

(51) Int. Cl. B22F 3/16; B28B 11/10; C03B 19/02; C03B 19/06

(52) U.S. Cl. CPC B22F 3/16; B28B 11/10; C03B 19/02; C03B 19/06; B22F 2202/03; B22F 2998/10

(57) ABSTRACT

A novel method for subzero molding and imprinting includes the steps of shaping a photo-curable resin at subzero temperatures, triggering a photo or thermal initiator to set the photo-curable resin in its shape to produce a substrate, and de-binding and sintering the substrate. The novel system includes a pneumatic punch press, a male mold core and a female mold cavity, a male imprinting bit, a cold plate, and a resin vat containing a photo-curable resin. The inventive system and method produce objects with a cell wall thickness of 10-100 μm all the way to very large dense parts with no size limitations and at much higher speeds than any existing conventional technologies.

### CROSS REFERENCE TO RELATED APPLICATIONS

This application claims priority to U.S. Provisional Application No. 63/279,160 filed Nov. 14, 2021, the contents of which are incorporated by reference in their entirety.

### FIELD OF THE INVENTION

The present invention relates to three-dimensional object manufacturing, and more particularly, to a system and method for subzero molding and imprinting three-dimensional objects.

### BACKGROUND OF THE INVENTION

In the last decade, traditional three-dimensional printing (3D printing) manufacturing, also referred to as additive manufacturing, has found widespread application, from end-use aerospace components to patient-tailored medical devices and bioprinting of tissues and organs to renewable energy sector applications. Such applications require additive manufacturing methods to produce accurate parts with a high throughput and high resolution, as well as to offer a wide range of printable materials. However, the sequential layer-by-layer operation of existing additive manufacturing has well-recognized drawbacks, including slow speed, low output, limited materials, high cost, geometric design restrictions, scaling, and structural defects.

Currently, most companies use photo curable resin with a Digital Light Processing projector for 3D printing with light. Those 3D printers are typically slow and limited in resolution as they utilize a layer-by-layer process that does not create objects with optically smooth surfaces. Additionally, it has proven almost impossible for most existing 3D printing technologies to print glass and other advanced materials like graphene silicon and stabilized zirconia.

To overcome the geometric constraints and throughput limitations of layer-by-layer light-based additive manufacturing techniques, namely digital-light processing (DLP) and stereolithography (SLA), multi-beam additive manufacturing techniques have been proposed. In multi-beam additive manufacturing, the object is not formed by sequentially curing layers of a photopolymer but rather created in a single step by irradiating a transparent resin bath from multiple angles, which results in the local accumulation of light dose and the consequent simultaneous solidification of specific object voxels. This process is also referred to as volumetric additive manufacturing. Though such volumetric part generation potentially yields higher throughput than existing DLP and SLA techniques and allows processing more viscous resins, the smallest feature size demonstrated by volumetric additive manufacturing is currently limited to approximately in the nano and micro resolution.

Presently, the clean energy and renewable energy sectors require a revolution of affordable and effective manufacturing technologies in order to sustainably compete in the market. In particular, solar power and battery energy fields have one of the biggest potentials for additive manufacturing improvements, which can greatly bring down the cost and/or increase efficiency of this resource.

### SUMMARY OF THE INVENTION

The present invention solves the above-mentioned drawbacks of the 3D printing manufacturing.

The present inventive deploys Layerless Subzero Molding of Photopolymers which can polymerize an object in one go similar to multi-beam additive manufacturing techniques.

The inventive technology utilizes a novel extension of photocurable resin used in additive manufacturing, more specifically, a class of light-sensitive resins that solidify when exposed to ultraviolet (UV) light. When the liquid photopolymer resin comes into contact with a UV light source—typically a lamp, laser, or projector—photo initiators transform that light energy into chemical energy. The present invention is able to freeze the whole UV Curable Resin Part and polymerize it in one shot utilizing concentrated sunlight which activates the photo initiator for high throughput layer-less volumetric manufacturing via subzero imprinting and molding with the inventive subzero pressure punching system.

The inventive technology utilizes UV curable binder resins to mix complex materials together which are frozen in molds similar to molding techniques not limited to extrusion, rotational, blow, compression, and injection molding. Normally you cannot form glass into complex 3D shapes but it is possible to volumetric 3D print and subzero mold UV curable matrix's into complex 3D shapes. Once the part is frozen in the mold, it is popped out of the mold onto a block of dry ice to keep its shape from melting. Then the shape of the design is set through UV Initiation through Concentrated Sunlight or an Artificial UV Curing Light Chamber which for High Throughput Layer-Less Volumetric Subzero Molding, Casting, and Imprinting.

The inventive technology is material agnostic and can mold, imprint, and cast materials not limited to: glass, silicon, cubic silicon carbide, metal, ceramic, and plastic, into flat and complex 3D shapes with an ultra-thin cell wall thickness from 10-2000 μm with non transparent materials and very large dense parts with transparent resin at speeds thousands of times faster than known additive manufacturing techniques. The depth of light penetration can be an issue for non-transparent materials.

This technology can be cast in mold impressions that are imprinted in blocks of Dry Ice or Silicone Molds. The resin is then poured into the 3D pattern that is imprinted into the block of dry and then the pressure machine quickly applies pressure via imprinting bit to make Structured 3D Glass and Yittria Stabilized Zirconia Ceramic as thin as a sheet of paper. This technology can be used for advanced manufacturing of 3D solar glass, and battery electrodes for Next Generation 3D Solar, Battery Cells, and Hypersonic Weapons.

The 3D structured glass can be millimeter thick or as thin as a sheet of paper 50 μm. In certain embodiments, the 3D structured glass can be embedded with 3D Photonic Crystals based on The Biomimicry of a fly's eye and a butterfly's wings. Biomimicry based manufacturing will yield the next generation of Advanced Technology.

The invention involves materials are not limited to traditional UV curable resin DLP 3D printing. The inventive technology takes recycled glass waste and repurposes the glass into particles that mix with resin, such as a Tethon Genesis Development 3D Printing Resin. The low-carbon process significantly decreases the balance of system cost of manufacturing. The inventive technology also takes very smooth volumetric 3d printed parts with a 3-4 nanometer surface finish and duplicates those master molds by imprinting the shape from the smooth part into silly putty or silicone molds. The process is not limited to just metal, polymer, and ceramic materials, and is material agnostic. The material footprint is so wide it can also be used to manufacture solid state batteries and complex hydrogen fuel cells. Once the master mold is made in metal, it can then be molded in the molds or casted into a block of dry ice. After the UV Resin is casted in a block of dry ice, then concentrated sunlight is applied to set the shape. After the shape is set then the UV binder resin is debinded at 650 C and then sintered at appropriate temperatures.

In certain embodiments, the Step 1 is freezing (see https://youtu.be/pubh6N75LNA) and Step 2 is the application of Concentrated Sunlight https://youtube.com/shorts/C5was6kw_Wk?feature=share.

The inventive technology enables Hyper Local Innovation via Next Generation Solar Manufacturing to expand the use of renewable energy and build a safe and resilient electricity system.

The inventive technology enables a prosperous future via plant-based UV curable binder resin that acts as a binder matrix for high and low-loading mixes of particles ranging from nanometer, micrometer in to millimeter size.

The inventive technology can form almost any material as a polymer into complex shapes at subzero temperatures. After the material is formed at subzero temperatures, it needs an UV initiator from light initiation to activate the initiator to set the resin in its shape. When a part is formed through duel curing or thermal activation, the activation happens first then the part is casted or molded. Thick dense parts can use thermal initiation or a duel curing method to make large parts with thicker cell walls.

Once the UV Curable Resin Photo Initiation has proceeded, an object will solidify in less than 10 seconds.

After the UV-Curable Resin Photo or Thermal Initiation has occurred, the object can stay at room temperature in its green state.

The next step requires the object in the green state to be debinded and sintered in an oven.

After the de-binding and sintering process finishes, the object usually shrinks 10-30% based on the material to binder resin ratio.

The inventive technology utilizes subzero temperatures and light to create a photo-initiation that sets the shape of the material as a polymer. The 3d shape freezes at subzero temperatures in a block of dry ice.

One of the goals of the present inventions is to competitively mass produce unique semiconductor, optical, and automotive components, which would be exceedingly difficult, if not impossible, for U.S. rival market competitors to reproduce, copy, and/or mimic.

These and other objects of the invention are achieved by providing a subzero pressure system, comprising: a pneumatic punch press, a male mold core and a female mold cavity, a male imprinting bit, a cold plate, and a resin vat containing a photo-curable resin, whereby the system is configured to cure the photo-curable resin.

In certain embodiments, the male imprinting bit comprises subcells with nanostructures, microstructures, and macro structures that form a larger male core imprinting bit that can be punched into a photo-curable resin matrix at subzero temperatures.

In certain embodiments, the male imprinting bit is cryogenically cooled in a cryogenic cold plate.

In certain embodiments, the male imprinting bit is hollow, transparent, and holds LEDS Lights.

In certain embodiments, the male imprinting bit uses pressure to set the 3D shape and light to initiate the Photo Initiation.

In certain embodiments, the resin vat has a precise spatiotemporal control via the cryogenic cold plate.

In certain embodiments, the male imprinting bit is configured to first punch nanostructures in the photo-curable resin and then punch micro or macro-3-dimensional shapes continuously.

In certain embodiments, the system is configured to mass produce objects with a cell wall thickness ranging from a nanometer, a micrometer, or macrometer.

In certain embodiments, the male imprinting Bit that has nano, micrometer, and millimeter structures that can be imprinted into silly putty or a block of dry ice for subzero casting.

In certain embodiments, the UV Curable Binder Resin is cast into mold impression's in a block of dry ice.

In certain embodiments, the system is combined with volumetric and continuous additive Manufacturing to speed up the process.

In certain embodiments, the system further includes a light chamber, the light chamber being used to set the photo initiation.

Other objects of the invention are achieved by providing a method for subzero molding and imprinting, comprising the steps of: shaping a photo-curable resin at subzero temperatures, triggering a photo or thermal initiator to set the resin in its shape to produce a substrate, and debinding and sintering the substrate.

In certain embodiments, the photo or thermal initiator is triggered at subzero temperatures to set nano porous, micro, and macro shapes.

In certain embodiments, the step of shaping the photo-curable resin comprises using a male imprinting bit.

In certain embodiments, the step of shaping the photo-curable resin comprises shaping the photo-curable resin with a punch press.

In certain embodiments, the punch press is a manual or pneumatic punch press.

In certain embodiments, the method mass produces objects with a cell wall thickness of about 10-100 μm.

In certain embodiments, the photo-curable resin is frozen in a cavity/core mold prior to the shaping step.

In certain embodiments, concentrated sunlight is used in the shape setting, debinding, and sintering into two steps rather than three steps.

In certain embodiments, Thermal Initiator or Duel Curing process replaces the UV Initiator.

In certain embodiments, silly putty, silicone, and/or dry ice are used for subzero molding and casting.

In certain embodiments, the method is performed using the subzero pressure system.

Other objects of the invention and its features and advantages will become more apparent from consideration of the following drawings and accompanying detailed description. The detailed description and specific examples, while indicating the preferred embodiment of the invention, are intended for purposes of illustration only and are not intended to limit the scope of the invention.

### BRIEF DESCRIPTION OF THE DRAWINGS

FIG. 1 is directed to a subzero pressure system using a pneumatic punch press, imprinting bit, resin vat, and liquid nitrogen line.

FIG. 2 is directed to a cryogenic cold plate.

FIG. 3 is directed to an exploded view of the cryogenic cold plate showing its subcell structure.

FIG. 4 is directed to a photograph of the subzero pressure system, with subzero cold plate with spatiotemporal temperature control and imprinting bit.

FIG. 5 is directed to an advertisement of the subzero pressure system.

FIG. 6 is directed to molds created by the subzero pressure system including recycled solar panel glass, and flexible glasses.

FIG. 7 is directed to an additional photographic schematic of an embodiment of the subzero pressure system.

FIG. 8 is directed to various molds created by the subzero pressure system.

FIG. 9 is directed to a dry ice block which can be used in embodiments of the invention.

FIG. 10 shows an ultra-thin micro structure fused silica made from the invention.

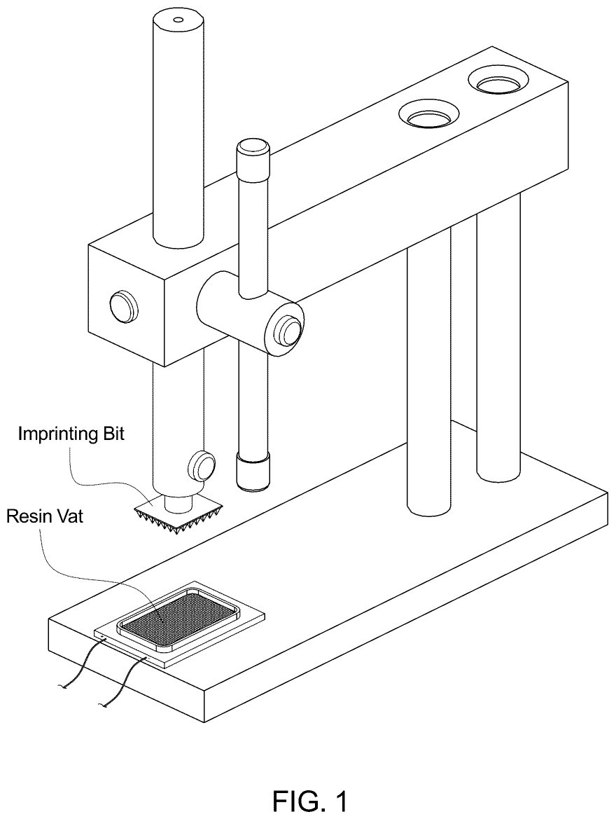

### DETAILED DESCRIPTION OF THE INVENTION

In the following description, numerous details are set forth for the purpose of explanation. However, one of ordinary skill in the art will realize that the invention may be practiced without the use of these specific details.

The subzero molding and imprinting technology of the present invention is material agnostic and can form nano, and micron material powders in a UV-curable resin with high and low loads of powder particles mixed in a photo curable resin matrix to form complex 3D shapes with cell wall thickness from about 10-100 μm, which is not achievable by any currently existing technologies. It is also possible to mold this UV-curable resin in a core and cavity mold with optically transparent resin and non-transparent UV-curable resin.

The inventive technology bypasses thin film deposition of particles. Instead, it uses a high or low viscosity UV-curable resin that acts as an attaching matrix to high and low loading mixes of powder particles ranging from nanometer to micrometer in size that are submerged in the resin matrix. This gives the inventive molding and imprinting technology the ability to form any material as a polymer at subzero temperatures.

After the material is formed at subzero temperatures, whether it is a thick solid piece or an ultra-thin flat or 3-dimensional sheet, it needs an initiator from light or thermal heat to activate the initiator to set the resin in its shape. Once the photo initiation of the UV-curable resin has occurred, the object should solidify in about 10 seconds or less while in its subzero state, thereby mitigating the heat risk which would normally deform the object because of photo polymerizing too quickly. After the UV-curable resin's photo or thermal initiation has occurred, the object can be left at room temperature where it then is in its green state. After this process, the object then has the UV-curable green state debinded and then it is sintered. After the debinding and sintering process, objects usually shrink 10-30% depending on how high the powder material is loaded in the photo curable resin matrix.

The present invention utilizes subzero temperatures, pressure, and light to create a photo-initiation that sets the shape of the material as a polymer. Shape can be set at subzero temperatures in a cavity/core mold, with the core being the male part which forms the internal shape of molding and the cavity being the female part which forms the external shape of molding, or with a male core mold attached to the system for continuous punching. A male core imprinting bit can in some instances be transparent and hollow where Micro LED Lights can be placed inside the male core imprinting bit so pressure and light can combine to shape the UV cryogenically frozen resin and initiate the photo initiation at the same time into 1 step rather than 2 steps.

Flat and 3-dimensional shapes can be set by the inventive system through the male core imprinting bit, wherein it is cooled cryogenically to punch three-dimensional low relief (or bas-relief) shapes in resin while at subzero temperatures. This process requires precise spatiotemporal control of the core male imprinting bit, cold plate, and photopolymer resin vat. Mold core and mold cavity can be designed in any structure, shape, or material.

In certain embodiments, concentrated sunlight is used to set the object's shape and to de-bind all in one step, thus significantly speeding up the manufacturing process of the present invention way above the known technologies.

In some embodiments, ultra-thin 3-dimensional and flat sheets may be produced that have a wall thickness of about 200 nm-20 μm. Such sheets may be scaled for advanced optics, solar cells, battery electrodes/anodes, and photo anodes for the solar to hydrogen conversion.

In some embodiments, a Thermal Initiator or Duel Curing mechanism replaces the UV Curable Photo Initiator.

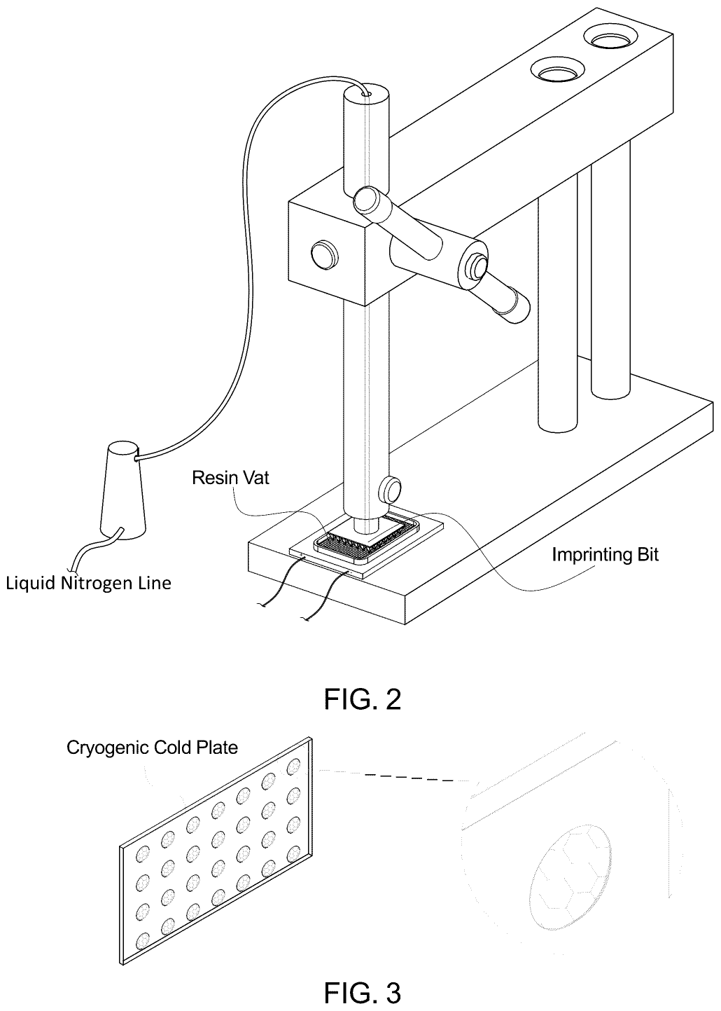

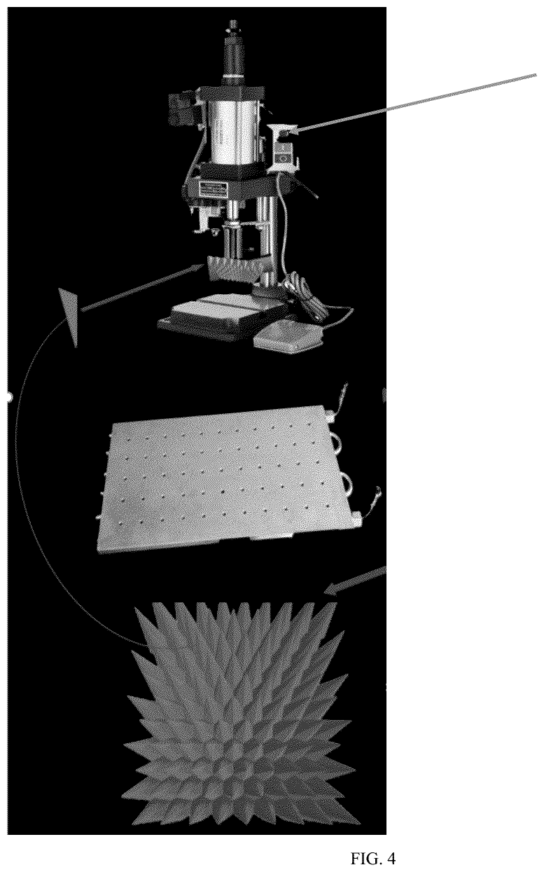

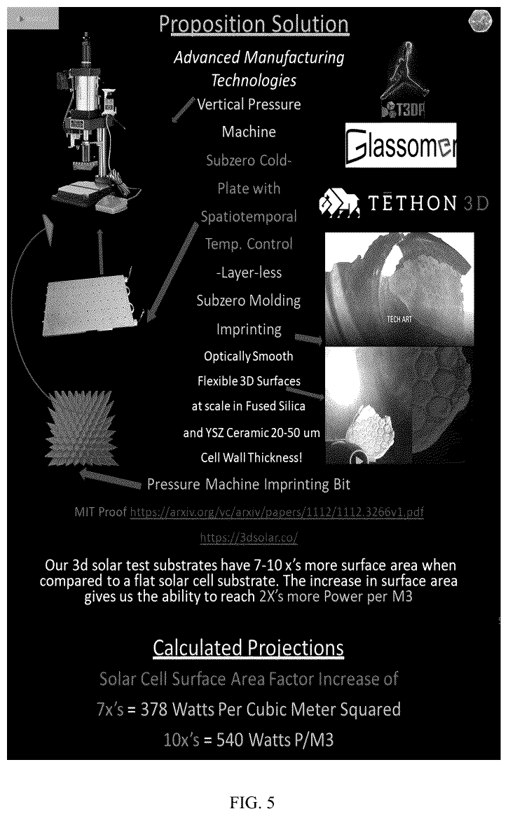

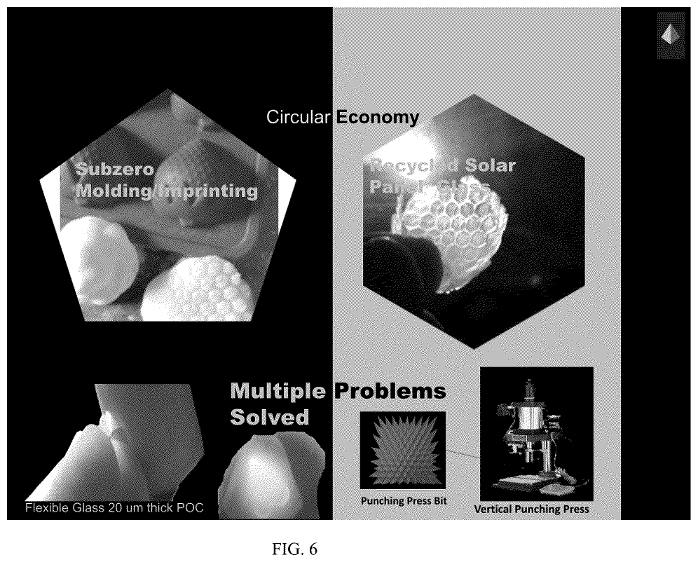

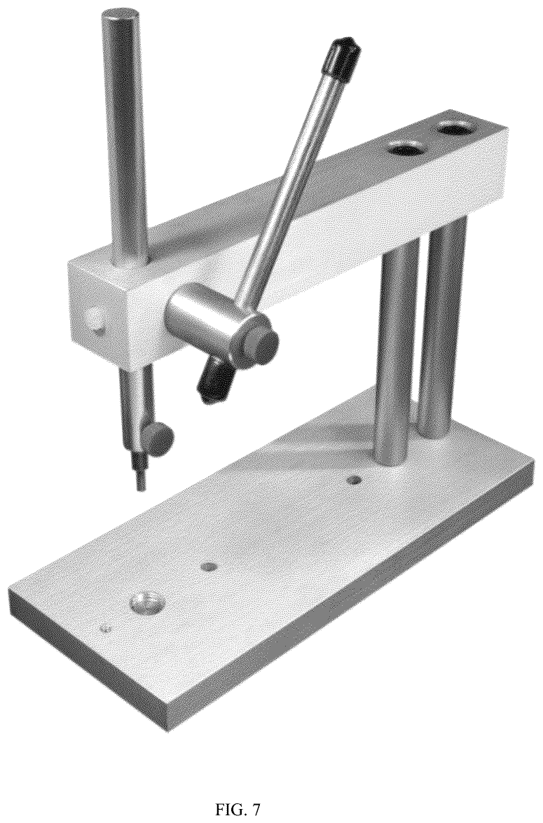

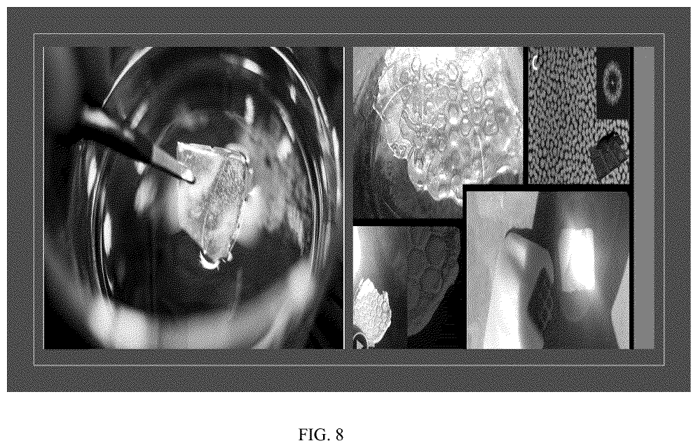

In some embodiments, as shown in FIG. 2, the Resin Vat and Core Male Imprinting Bit is Cryogenically Cooled.

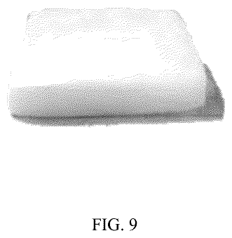

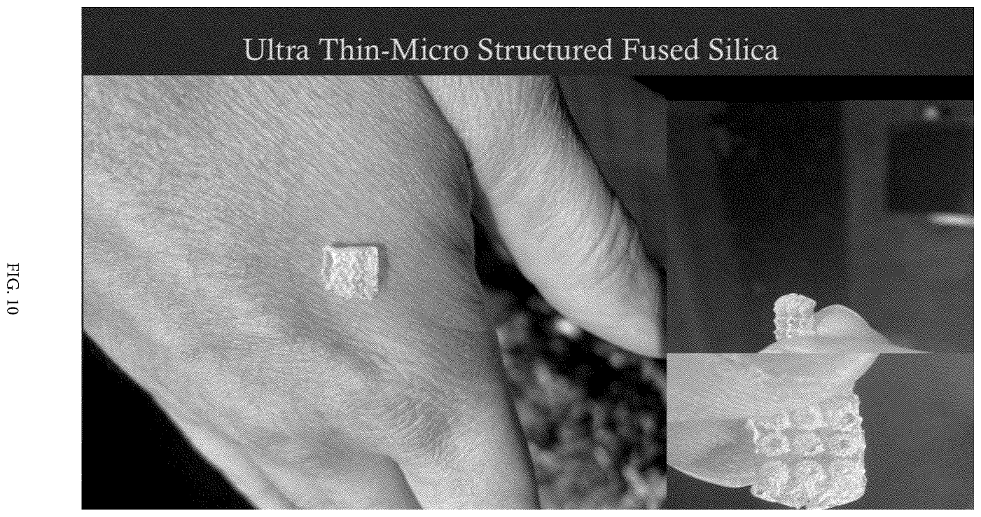

In some embodiments the Male Imprinting Bit is slowly pressed into the block of dry ice as shown in FIG. 9.

In some embodiments the UV curable binder resin is poured into the block of dry to be subzero casted into its 3D shape.

In some embodiments a UV Curable Resin is injected into the mold to replicate injection molding.

In some embodiments, the UV Curable, Thermal Set, or Duel Curing Resin is molded in a silicone, silicone polymers, silly putty, metal, polymer, ceramic, dry ice, or any other materials as the mold.

In some embodiments the UV Binder Resin can be molded with a silly putty (or silicone polymer) master made from a optically smooth 3-4 nm surface finish part to create a mold impression in the silly putty or silicone mold. Once the metal master male imprinting bit is made from metal it can be used to make a mold casting impression in a block of dry ice.

Having thus described several embodiments for practicing the inventive method, its advantages and objectives can be easily understood. Variations from the description above may and can be made by one skilled in the art without departing from the scope of the invention.

Accordingly, this invention is not to be limited by the embodiments as described, which are given by way of example only and not by way of limitation.

### REFERENCES

1. #SubzeroCasting #Flexible3DGlass: https://youtu.be/pubh6N75LNA
2. #HyperLocal #ManufacturingOnePager https://docs.google.com/presentation/d/1pgpD6WlWOvXebvCfuQrORT7AxSuVu8YU/edit?usp=sharing&ouid=116932139894033358829&rtpof=true&sd=true
3. #Sphereical3DSolar https://www.youtube.com/watch?v=nuDLfW3-DT4
4. #FormingGlassAsPolymer https://www.youtube.com/watch?v=5FZhK5TqZNQ&feature=youtu.be
5. #IMECBelgium #3DSolarEvaluation https://docs.google.com/presentation/d/1qMkFw6Nro-iyjYrBA2kJ_lbnAQxHMmeD/edit?usp=sharing&ouid=113492622968538717434&rtpof=true&sd=true

1.-23. (canceled)

24. A subzero pressure system, comprising:
a pneumatic punch press,
a male mold core and a female mold cavity,
a male imprinting bit,
a cold plate, and
a resin vat containing a photo-curable resin,
whereby the system is configured to cure the photo-curable resin.

25. A casting/molding system, comprising:
a female cavity containing photocurable resin, and
a Silicone, Metal, Polymer, Ceramic, or Glass Mold Cavity,
whereby the system is configured to cure the photo-curable resin when exposed to light or heat.

26. The system of claim 24, where the male imprinting bit is hollow and transparent, and holds LEDS Lights to enable stamping/imprinting of nano and microstructures in the semi-frozen photocurable resin when below 0 degrees F.

27. The system of claim 24, where the male imprinting bit uses pressure to set the 3D shape and light from LEDS inside the hollow nano/micro imprinting bit to initiate the Photo Initiation at subzero temperatures of glass-filled resin in one-step.

28. The system of claim 25, wherein glass, ceramic, metal, or semiconductor is loaded into UV Curable Binder Resin and cast into the mold cavity where it is Photo, Thermal or Co-Initiated with other materials to polymerize the part into its green state.

29. The system of claim 25, where Photo or Thermal Curable Resin, or a combination thereof is cast or injected into the mold cavity where the shape is set while the resin is in the mold cavity via light or thermal initiation.

30. A method for casting/molding and imprinting, comprising the steps of:
shaping a photo-curable resin at room and subzero temperatures in a vat or mold,
triggering a photo or thermal initiator to set the resin in its shape to produce a substrate, and
debinding and sintering the substrate.

31. The method of claim 30, wherein the glass, metal, semiconductor, or ceramic-filled resin is cast into a female mold via mechanical pressure or air pressure.

32. The method of claim 30, wherein the step of shaping the photo-curable resin includes using a male imprinting bit to continuously stamp the desired shape into the resin, which is progressively moved forward along an assembly line to allow successive stamping of subsequent sections.

33. The method of claim 30, wherein the photo-curable resin is room temp or chilled below 0 degrees Fahrenheit in a cavity/core mold before thermally or photo initiating the 3d printing resin.

34. The method of claim 30, wherein the Thermal Initiator replaces or combines with the Photo-Initiator.

35. The method of claim 30, wherein silicone, silly putty, polymer, metal, glass, or a block of dry ice is used for casting the resin filled with solid materials into the vat or the mold.
